(19) United States
(12) Patent Application Publication
(10) Pub. No.: US 2025/0081484 A1
(43) Pub. Date: Mar. 6, 2025

(54) SEMICONDUCTOR DEVICE WITH ZENER DIODE AND METHOD FOR MANUFACTURING

(71) Applicant: Infineon Technologies Austria AG, Villach (AT)

(72) Inventors: Dirk Priefert, Moers (DE); Andrei Sidelnicov, Dresden (DE); Christian Schippel, Dresden (DE)

(21) Appl. No.: 18/825,668

(22) Filed: Sep. 5, 2024

(30) Foreign Application Priority Data
Sep. 6, 2023 (DE) 102023208611.5

(51) Int. Cl. H01L 29/866; H01L 29/06; H01L 29/66

(52) U.S. Cl. CPC H10D 8/25; H10D 8/022; H10D 62/125

(57) ABSTRACT

A lateral semiconductor device includes: a semiconductor substrate; a first insulator layer formed on the semiconductor substrate; and a semiconductor layer formed on the first insulator layer opposite to the semiconductor substrate. The semiconductor layer includes a first region of a first conductivity type, a second region of a second conductivity type opposite to the first conductivity type, and an intermediate region interposed between the first region and the second region and defining a first lateral distance between the first region and the second region. The intermediate region has a lower doping concentration than the first region and the second region. A doping concentration of the first region at an interface to the intermediate region and a doping concentration of the second region at an interface to the intermediate region both exceed 1×10¹⁸ cm⁻³. The first lateral distance is at most 800 nm.

### TECHNICAL FIELD

The present disclosure relates to a lateral semiconductor device comprising two doped regions in semiconductor layer. More particular, the lateral semiconductor device may be a silicon on insulator (SOI) device comprising a Zener diode. The present disclosure further relates to a method of manufacturing a semiconductor device.

### BACKGROUND

Semiconductor chips in SOI technology may comprise a plurality of different devices. The different devices may form an integrated circuit (IC) therein. The SOI technologies may be used to implement a low power and/or low voltage devices, e.g. formed in a CMOS technology (complementary metal oxide semiconductors) into a high voltage semiconductor chip. Therefore, HV (high-voltage) semiconductor devices in CMOS technology (complementary metal oxide semiconductors) form an interface between standard CMOS devices with input voltages up to 5V on the one hand and industrial or consumer circuits operating with signal voltage levels above 30V or even above 200V on the other.

Applications for such HV semiconductor devices exist in all kinds of power conversion and electrical drives up to the kW range, e.g., in power converters, robotics and the automotive industry. Such HV semiconductor devices typically include a low voltage part as a low voltage domain and a HV part as a high voltage domain. In the low voltage part, most of the signal processing is done at low operating voltage. The HV part operates at higher voltage level and provides a signal interface for power semiconductors using higher voltage levels and/or having higher current driving and sinking capability. An example of such a HV semiconductor device is a gate driver circuit that allows a microcontroller or DSP (digital signal processor) to efficiently turn on and off power semiconductor switches. HV terminations separate two or more CMOS circuits in different voltage domains, whose potentials can differ by several 100V up to some 1000V. The lateral width of the HV termination depends on the required voltage breakdown capability between the voltage domains. The HV termination may include a field plate structure and often occupies a significant portion of the HV semiconductor device. Examples of a semiconductor device integrated in the SOI technologies are MOSFETs, pn diodes, Zener diodes, and many more.

There is a constant need to improve the electric properties as well as the manufacturability of such semiconductor devices.

### SUMMARY

According to an embodiment, a lateral semiconductor device comprises a semiconductor substrate, a first insulator layer formed on the semiconductor substrate, and a semiconductor layer formed on the first insulator layer opposite to the semiconductor substrate. The semiconductor layer comprises a first region of a first conductivity type, a second region of a second conductivity type opposite to the first conductivity type, and an intermediate region interposed between the first and the second region, wherein the intermediate region comprises a lower doping concentration than the first and the second region, wherein the first and the second region form a Zener diode.

According to a further embodiment, a lateral semiconductor device comprises a semiconductor substrate, a first insulator layer formed on the semiconductor substrate, and a semiconductor layer formed on the first insulator layer opposite to the semiconductor substrate. The semiconductor layer comprises a first region of a first conductivity type, a second region of a second conductivity type opposite to the first conductivity type, and an intermediate region interposed between the first and the second region defining a first lateral distance between the first and the second region, wherein the intermediate region comprises a lower doping concentration than the first and the second region, wherein a doping concentration of the first region at an interface to the intermediate region and a doping concentration of the second region at an interface to the intermediate region exceeds 1×10¹⁸ cm⁻³, and wherein the first lateral distance between the first and the second region is at most 800 nm.

According to a further embodiment, a method for forming lateral semiconductor device comprises providing a semiconductor stack, the semiconductor stack comprising a semiconductor substrate, a first insulator layer formed on the semiconductor substrate, and a semiconductor layer formed on the first insulator layer opposite to the semiconductor substrate. The method further comprises forming a Zener diode by implanting first dopants to form a first region of a first conductivity type within the semiconductor layer, and implanting second dopants to form a second region of a second conductivity type opposite to the first conductivity type within the semiconductor layer, wherein the first and the second dopants are implanted with a second lateral distance from each other in order to form an intermediate region interposed between the first and the second region, wherein the intermediate region comprises a lower doping concentration than the first and the second region.

According to a further embodiment, a method for forming lateral semiconductor device comprises providing a semiconductor stack, the semiconductor stack comprising a semiconductor substrate, a first insulator layer formed on the semiconductor substrate, and a semiconductor layer formed on the first insulator layer opposite to the semiconductor substrate. The method further comprises the following steps: Implanting first dopants to form a first region of a first conductivity type within the semiconductor layer; Implanting second dopants to form a second region of a second conductivity type opposite to the first conductivity type within the semiconductor layer, wherein the first and the second dopants are implanted with a second lateral distance of 50 nm to 800 nm; and recrystallizing at least portions of the first and the second region after implanting the first and the second dopants.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIGS. 1A through 1C illustrate a first exemplary embodiment of a Zener diode.

FIGS. 2A through 2C illustrate a second exemplary embodiment of a Zener diode.

FIG. 3 illustrates an exemplary method of manufacturing a lateral semiconductor device.

FIGS. 4A and 4B illustrate an exemplary mask setup of a method of manufacturing a lateral semiconductor device.

### DETAILED DESCRIPTION

The examples described herein provide a lateral semiconductor device comprising a semiconductor substrate, a first insulator layer formed on the semiconductor substrate, and a semiconductor layer formed on the first insulator layer opposite to the semiconductor substrate. The semiconductor layer comprises a first region of a first conductivity type, a second region of a second conductivity type opposite to the first conductivity type, and an intermediate region interposed between the first and the second region, wherein the intermediate region comprises a lower doping concentration than the first and the second region, wherein the first and the second region form a Zener diode.

The examples described herein further provide a lateral semiconductor device comprising a semiconductor substrate, a first insulator layer formed on the semiconductor substrate, and a semiconductor layer formed on the first insulator layer opposite to the semiconductor substrate. The semiconductor layer comprises a first region of a first conductivity type, a second region of a second conductivity type opposite to the first conductivity type, and an intermediate region interposed between the first and the second region defining a first lateral distance between the first and the second region, wherein the intermediate region comprises a lower doping concentration than the first and the second region, wherein a doping concentration of the first region at an interface to the intermediate region and a doping concentration of the second region at an interface to the intermediate region exceeds 1×10¹⁸ cm⁻³, and wherein the first lateral distance between the first and the second region is at most 800 nm.

According to a further embodiment, a method for forming lateral semiconductor device comprises providing a semiconductor stack, the semiconductor stack comprising a semiconductor substrate, a first insulator layer formed on the semiconductor substrate, and a semiconductor layer formed on the first insulator layer opposite to the semiconductor substrate. The method further comprises forming a Zener diode by implanting first dopants to form a first region of a first conductivity type within the semiconductor layer, and implanting second dopants to form a second region of a second conductivity type opposite to the first conductivity type within the semiconductor layer, wherein the first and the second dopants are implanted with a second lateral distance from each other in order to form an intermediate region interposed between the first and the second region, wherein the intermediate region comprises a lower doping concentration than the first and the second region.

According to a further embodiment, a method for forming lateral semiconductor device comprises providing a semiconductor stack, the semiconductor stack comprising a semiconductor substrate, a first insulator layer formed on the semiconductor substrate, and a semiconductor layer formed on the first insulator layer opposite to the semiconductor substrate. The method further comprises the following steps: Implanting first dopants to form a first region of a first conductivity type within the semiconductor layer; Implanting second dopants to form a second region of a second conductivity type opposite to the first conductivity type within the semiconductor layer, wherein the first and the second dopants are implanted with a second lateral distance of 50 nm to 800 nm; and recrystallizing at least portions of the first and the second region after implanting the first and the second dopants. The semiconductor layer provided for each of the methods may be at least at least partly monocrystalline.

The following examples of features can be combined with any of the above-mentioned examples and among each other.

For example, a doping concentration of the first region at an interface to the intermediate region and a doping concentration of the second region at an interface to the intermediate region exceeds 1×10¹⁸ cm⁻³. In other words, the doping concentration region of the first region may exceed 1×10¹⁸ cm⁻³ at least near the intermediate region. The doping concentration region of the second region may exceed 1×10¹⁸ cm⁻³ at least near the intermediate region. The doping concentration of the first region may be at least by a factor of five (5) or even by at least a factor of ten (10) greater than the doping concentration of the second region.

For example, a first lateral distance between the first and the second region defined by the intermediate region is at most 800 nm. For example, the first lateral distance may be at most 600 nm. For example, the first lateral distance may be in a range from 50 nm to 800 nm or in a range from 200 nm to 600 nm. A second lateral distance may define the first lateral distance during the implantation process of the first and the second dopants. The second lateral distance is the distance of the implantation regions, while the first lateral distance is the distance between the semiconductor region resulting from the implantations. The first and the second lateral distance may, however, be slightly different. The second lateral distance may be at most 800 nm or at most 600 nm. The second lateral distance may be in a range from 50 nm to 800 nm or in a range from 200 nm to 600 nm.

For example, the first lateral distance equals a lateral extension of the intermediate region between the first and the second region. In other words, the lateral gap between the first and the second region may at least along a vertical portion of said gap be fully occupied by the intermediate region. The intermediate region may extend vertically over the full thickness of the semiconductor layer. As such, a vertical extension of the intermediate region may be equal to or greater than the vertical extension of the first and/or the second region. The intermediate region may occupy the complete gap between the first and the second region.

For example, the intermediate region fully separates the first and the second region. As such, the first and the second region may, for example, be fully distanced from each other.

For example, each of the first region, the second region and the intermediate region adjoins the first insulator layer. As such, all three regions may comprise respective boundary surfaces to the first insulator layer that are oriented within the same plane and/or parallel to each other on the same vertical level.

For example, the lateral semiconductor device further comprises a second insulator layer formed on the semiconductor layer opposite to the first insulator layer. The semiconductor layer may be at least partly sandwiched between the first insulator layer and the second insulator layer.

For example, each of the first region, the second region and the intermediate region adjoins both of the first and the second insulator layer. As such, all three regions may comprise respective boundary surfaces to the first insulator layer that are oriented within the same plane and/or parallel to each other on the same vertical level. Additionally or alternatively, all three regions may comprise respective boundary surfaces to the first insulator layer that are oriented within the same plane and/or parallel to each other on the same vertical level.

For example, at least between the first and the second insulator layer, the first and the second region interface only via the intermediate region. For example, the first and the second region may be electrically connected only via the intermediate region.

For example, the intermediate region comprises only a background doping. The backside doping may, for example, be at most 1×10¹⁶ cm⁻³. The background doping be defined as the doping incorporated into the silicon layer during a manufacturing, e.g. a crystal growth and/or an EPI, of the silicon layer. The background doping may be the doping of the silicon layer without any additionally added dopants after the silicon layer is formed, e.g. without any implantation or in-diffusion of dopants.

For example, the intermediate region comprises a doping concentration of at most 3×10¹⁹ cm⁻³. For example, the doping concentration of the intermediate region is only of at most 3×10¹⁸ cm⁻³ or even at most 3×17¹⁷ cm⁻³. Alternatively or additionally, the doping concentration of the intermediate region is at least by a factor of two smaller than the doping concentration of both the first and the second region. For example, the doping concentration of the intermediate region is at least by one magnitude smaller than the doping concentration of both the first and the second region. A pn junction between the first and the second region may be formed within the intermediate region. By diffusion of dopants from the first and/or the second region into the intermediate region, the pn junction may be formed. In a thermal annealing step, the active pn junction may be formed after the implant of both the first and the second dopants, e.g. by said diffusion from the first and/or the second region into the intermediate region. Said pn junction may the pn junction of that is formed between the first and the second region. Hence the pn junction of the Zener diode between the first and the second region may be located in the intermediate region.

For example, the intermediate region is monocrystalline. The intermediate region may be monocrystalline throughout the implantation of the first and the second region into the semiconductor layer. The intermediate region may be spared throughout the implantation of the first and the second dopants into the first and the second region. For example, the intermediate region may be covered by a mask arrangement during the implantation of both the first and the second dopants. The mask arrangement may comprise a photo resist layer, a hard mask (e.g. an oxide as SiO or a nitride as SiN), an oxide or nitride layer, or a combination thereof. As a result of the omission of the intermediate region during the implantation process steps, the doping concentration is smaller compared to the first and the second region. For example, the doping concentration in the intermediate region is smaller by at least a factor of two (2) compared to a maximum of the doping concentration within the first and the second region. For example, the doping concentration in the intermediate region is smaller by at least one magnitude or even by at least two magnitudes compared to a maximum of the doping concentration within the first and the second region. Additionally, the crystal lattice is not bothered by the implantation resulting in a monocrystalline structure of the intermediate region after the implantation of the first and second dopants, while the crystal lattice in the first and second region may be affected or even destroyed due to the high implantation doses of the first and the second dopants. This crystal damage within the first and the second region would, without the intermediate region as a spacer, lead to an increased leakage current of the Zener diode. The monocrystalline intermediate region may lower the leakage current. Furthermore, the intermediate region may form a seed layer for a recrystallization of at least portions of the first and the second region. Without the intermediate region as seed layer, it may not be possible to recrystallize the first and the second region. As a result, the pn junction (which may be located in the intermediate region) may be surrounded by monocrystalline portions of the first and the second region. For example, each of the first region, the second region and the intermediate region is at least partly monocrystalline. This may lead to an even further reduced leakage current and an increased lifetime and electrical stability of the semiconductor device.

For example, the semiconductor layer may have a thickness of at most 400 nm. In another example, the semiconductor layer may have a thickness of at most 250 nm.

For example, the semiconductor device comprises a first field stop region adjoining the first semiconductor region and a second field stop region adjoining the second semiconductor region, wherein the intermediate region further separates the first field stop region and the second field stop region. The intermediate region may protrude laterally from the gap between the first and the second region to a gap between the first field stop region and the second field stop region. The first field stop region may laterally adjoin the first region and the intermediate region. The first field stop region may have the first conductivity type but with lower doping concentration compared to the first region. The second field stop region may laterally adjoin the second region and the intermediate region. The second field stop region may have the second conductivity type but with lower doping concentration compared to the second region. The first and the second field stop region may be sandwiched between the first insulator layer and the second insulator layer.

For example, the semiconductor device comprises a conductive layer above the second insulator layer. The conductive layer may comprise highly doped polysilicon or, preferably, a metal. The first and the second regions may be contacted to the conductive layer via respective contact plugs extending through the second insulator layer. The conductive layer may be laterally segmented, wherein the first and second region are electrically connected to different portions of the conductive layer.

For example, the first insulator layer may, for example, comprise an oxide, e.g. silicon oxide, or a nitride, e.g. silicon nitride. In case of silicon oxide, the oxide may for example be thermally grown oxide or a deposited oxide. The first insulator layer may comprise more than one sublayer. Each of the sublayers of the first insulator layer may have a different chemical composition. For example, the second insulator layer may, for example, comprise an oxide, e.g. silicon oxide, or a nitride, e.g. silicon nitride. In case of silicon oxide, the oxide may for example be thermally grown oxide or a deposited oxide. The second insulator layer may comprise more than one sublayer. Each of the sublayers of the second insulator layer may have a different chemical composition.

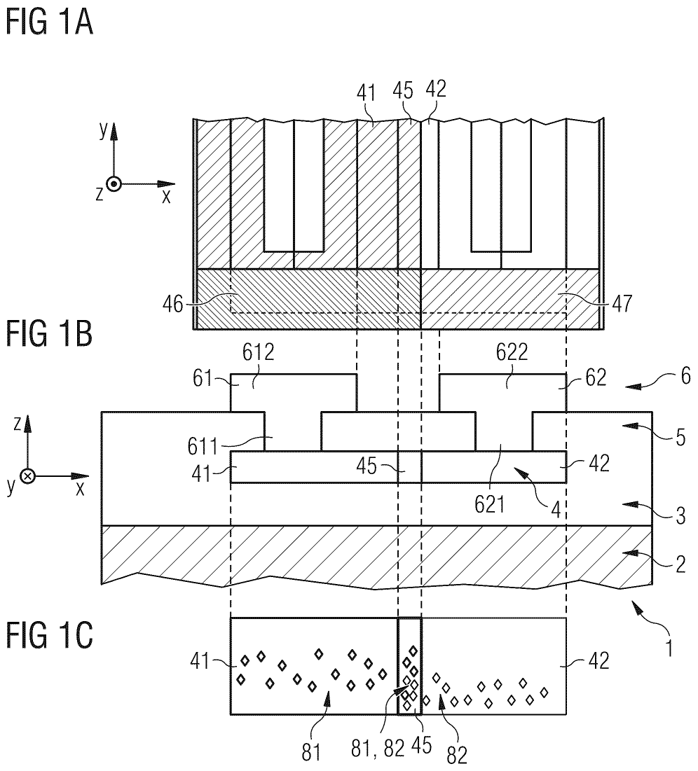

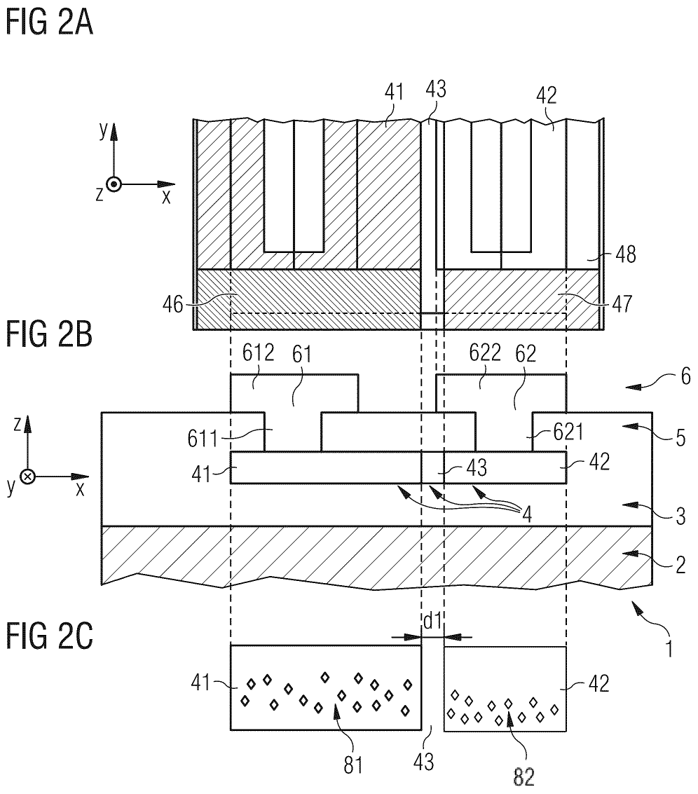

Reference is now made to FIGS. 1A-1C and 2A-2C. FIGS. 1A-1C and 2A-2C schematically depict a lateral semiconductor device 1. FIGS. 1B and 2B show a section through the respective device 1. FIGS. 1A and 2A show a vertical projection along a vertical axis z similar to a top view. The vertical axis z is perpendicular two both lateral axes x, y.

Still referring to FIGS. 1A-1C and 2A-2C, the lateral semiconductor device 1 comprises a semiconductor substrate 2. The semiconductor substrate 2 may originate from a monocrystalline silicon wafer. A thickness of the semiconductor substrate 2 may be in a range from 20 μm to 200 μm. The device 1 comprises a first insulator layer 3 above the semiconductor substrate 1. The device 1 further comprises a semiconductor layer 4 above the first insulator layer 3. The semiconductor layer 4 may be the only semiconductor layer of the lateral semiconductor device 1 having comprising active devices. In other words, the lateral semiconductor device 1 may be devoid of any semiconductor layer above or below the semiconductor layer 4 comprising electrically active semiconductor devices. Hence the semiconductor layer 4 may be the only device layer of the lateral semiconductor device 1. The semiconductor layer 4 may have a thickness of 100 nm to 250 nm. The device 1 further comprises a second insulator layer 5 above the semiconductor layer 4. The semiconductor layer 4 is sandwiched between the first insulator layer 3 and the second insulator layer 5.

A metallization comprises a metal layer 6 above the second insulator layer 5 and contact plugs 611, 621 extending through the second insulator layer 5. The second insulator layer 5 is laterally segmented into portions 612, 622. The portions 612 and 622 form a contact pad each.

Still referring to FIGS. 1A-1C and 2A-2C, the semiconductor layer 4 comprises a first region 41 and a second region 42. The first region 41 has a first conductivity type, e.g. the n-type. The second region 42 has a second conductivity type opposite to the first conductivity type, e.g. the p-type. The first region 41 is connected to a first contact pad 612 via a first contact plug 611. The first contact plug 611 extends through the second insulator layer 5. The second region 42 is connected to a second contact pad 622 via a second contact plug 621. The second contact plug 621 extends through the second insulator layer 5. The first region 41 forms a cathode region of a Zener diode and the second region forms an anode region the Zener diode. The first contact pad 612 forms a cathode electrode of the Zener diode and the second contact pad 622 forms an anode electrode of the Zener diode. The contact plugs 611, 621 may form an ohmic contact to the respective semiconductor region 41, 42. The first and the second region 41, 42 may each have a doping concentration of a least 1×10¹⁸ cm⁻³.

Now referring to FIGS. 1A-1C, an overlap region 45 is formed between the first region 41 and the second region 42. In the overlap region 45, dopant of the first and the second conductivity type are implanted. In the overlap region 45, the implants for forming the first region 41 and the second region 42 overlap. FIG. 1C gives a schematic overview over the distribution of the first dopants 81 of the first region 41 and the second dopant 82 in the second region 42. In other words, both the first and the second region extend into the overlap region 45, where both the first and the second dopants 81, 82 are present. Thus, the overall doping concentration is higher in the overlap region 45 when compared to the first region 41 or the second region 42. This leads to an increasing crystal damage within the overlap region 45. This may result in an increased leakage current and faster degradation of the semiconductor device 1.

Now referring to FIGS. 2A-2C, the first region 41 and the second region 42 are spaced apart by a first lateral distance d1 (parallel to the first lateral direction x). In other words, the first region 41 and the second region 42 do not border each other or even overlap each other. They are spaced apart from each other by an intermediate region 43. In the present embodiment, the first lateral distance d1 is in a range from 50 nm to 800 nm and preferably in a range from 200 nm to 600 nm. The intermediate region 43 is interposed between the first 41 and the second region 42. The intermediate region 43 comprises a lower doping concentration than each of the first region 41 and the second region 42. The intermediate region 43 may be masked during the implantation of both the first region 41 and the second region 42 (cf. FIGS. 4A and 4B). FIG. 2C gives a schematic overview over the distribution of the first dopants 81 of the first region 41 and the second dopant 82 in the second region 42. In the intermediate region 43, no first and second dopants 81, 82 are present or they are present but with a lower dose compared to the neighboring portions of the first and second region 41, 42.

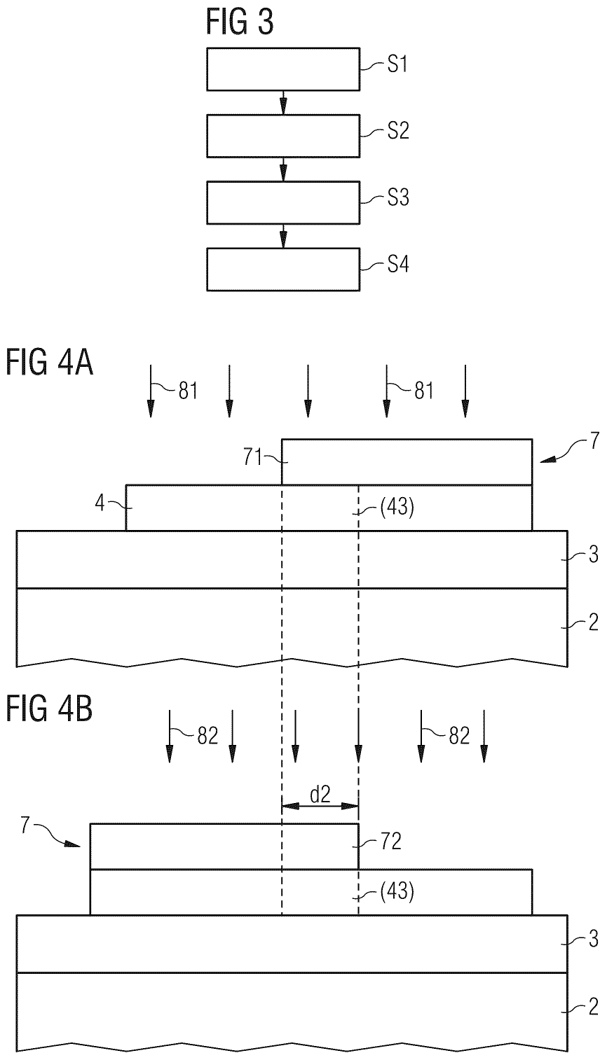

Now referring to FIG. 3, a method for manufacturing a lateral semiconductor device is provided. In a first step S1 a semiconductor stack comprising a semiconductor substrate 2, a first insulator layer 3 formed on the semiconductor substrate 2, and a semiconductor layer 4 formed on the first insulator layer 3 opposite to the semiconductor substrate 2 is provided. The semiconductor layer 4 is at least partly monocrystalline. In subsequent steps a Zener diode is formed by implanting (S2) first dopants 81 to form a first region 41 of a first conductivity type within the semiconductor layer and implanting (S3) second dopants 82 to form a second region 42 of a second conductivity type opposite to the first conductivity type within the semiconductor layer 2. The first and the second dopants 81, 82 are implanted with a second lateral distance d2 (parallel to the first lateral direction x) from each other in order to form an intermediate region 43 interposed between the first region 41 and the second region 42, wherein the intermediate region 43 comprises a lower doping concentration than each of the first and the second region 41, 42. In the present embodiment, the second lateral distance d2 is in a range from 50 nm to 800 nm and preferably in a range from 200 nm to 600 nm.

Now referring to FIGS. 4A and 4B, the implantations process steps S2 and S3 of FIG. 3 are described in more detail. FIG. 4A shows the process during the implantation of the first dopants 81, where parts of the semiconductor layer 4 are masked by a first mask arrangement 71. The first mask arrangement 71 covers (at least) the portions of the semiconductor layer 4 that are indicated to form the second region 42 and the intermediate region 43 later. The first dopants 81 are implanted into the semiconductor layer 4 only where the first region 41 is intended to be formed. For example, the first dopants 81 are implanted with dose in a range from 1×10¹⁵ cm⁻² to 6×10¹⁵ cm⁻². FIG. 4B shows the process during the implantation of the second dopants 82, where parts of the semiconductor layer 4 are masked by a second mask arrangement 72. The second mask arrangement 72 covers (at least) the portions of the semiconductor layer 4 that are indicated to form the first region 41 and the intermediate region 43 later. The second dopants 82 are implanted into the semiconductor layer 4 only where the second region 42 is intended to be formed. The second dopants 82 are implanted with dose of 1×10¹⁴ cm⁻² to 4×10¹⁵ cm⁻². “Implanted only” into a certain region means is to be understood with the technical possibilities in mind and the intention of the mask arrangement 71. Traces of the dopants below the masked areas cannot be excluded by 100%. Therefore “only” means to at least 99% in this context. The mask arrangements 71, 72 may comprise a photo resist layer, a hard mask (e.g. an oxide as SiO or a nitride as SiN), an oxide or nitride layer, or a combination thereof.

The intermediate region 43 is spared masked during the implantation of the first and the second dopants 81, 82. Therefore, the intermediate region 43 suffers a lower extent of crystal damage during the implantation processes S2 and S3. The crystal lattice of the intermediate region 43 remains therefore intact. Now referring back to FIG. 3, in a further steps S4, at least portions of the first and the second region 41, 42 are recrystallized. This may be done by heating the semiconductor layer, for example in an oven, by a rapid thermal anneal (RTA) or by laser thermal anneal (LTA).

During the tempering step the recrystallization or in a separate tempering step, dopants of the first region 41 and the second region 42 may be diffused into the intermediate region 43. According to the example of FIGS. 2A-2C, the intermediate region 43 comprises a doping concentration of at most 1×10¹⁷ cm⁻³ even after the diffusion is finished and in the final product. According to the example of FIGS. 2A-2C, the intermediate region 43 comprises a doping concentration by at least a factor of ten or even a factor of fifty (50) smaller than in the first region 41 and/or the second region 42 even after the diffusion is finished and in the final product. The pn junction of the Zener diode may be formed within the intermediate region 43 by the diffusing of the first dopant 81 and the second dopant 82 into the intermediate region 43.

Now referring again to FIGS. 1A-1C and 2A-2C, the semiconductor device 1 comprises a first field stop region 46 adjoining the first semiconductor region 41 (in the second lateral direction y) and a second field stop region 47 adjoining the second semiconductor region 42 (in the second lateral direction y). In FIGS. 2A-2C, the intermediate region 43 further separates the first field stop region 46 and the second field stop region 47. The intermediate region 43 protrudes laterally from the gap between the first and the second region 41, 42 to a gap between the first field stop region and the second field stop region. The first field stop region 46 laterally adjoins the first region 41 (in the second lateral direction y) and the intermediate region 43 (in the first lateral direction x). The first field stop region 46 has the first conductivity type but with lower doping concentration compared to the first region 41. The second field stop region 47 laterally adjoins the second region 42 (in the second lateral direction y) and the intermediate region 43 (in the first lateral direction x). The second field stop region 47 may have the second conductivity type but with lower doping concentration compared to the second region 42. The first and the second field stop region 46, 47 are sandwiched between the first insulator layer and the second insulator layer.

Referring to FIGS. 2A-2C, the distance d1 can be placed arbitrarily between the contact plugs 61, 62, but it is not purely random, because each of the semiconductor regions 41, 42 must not reach the respective opposite contact plug 61, 62 by diffusion. This would lead to a resistor instead of a diode. In the embodiment, the first semiconductor region 41 has a higher doping concentration than the second semiconductor region 42. In the embodiment, the more highly doped of the two semiconductor regions 41, 42 has a greater lateral extension along the X-axis. More particular, the first semiconductor region 41 has a greater lateral extension along the X-axis between the contact plugs 61, 62 than the second semiconductor region 42. Because of the higher doping concentration of the first semiconductor region 41, this achieves a lower overall electrical resistance of the Zener diode.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A lateral semiconductor device, comprising:
a semiconductor substrate;
a first insulator layer formed on the semiconductor substrate; and
a semiconductor layer formed on the first insulator layer opposite to the semiconductor substrate,
wherein the semiconductor layer comprises:
a first region of a first conductivity type;
a second region of a second conductivity type opposite to the first conductivity type; and
an intermediate region interposed between the first and the second region,
wherein the intermediate region comprises a lower doping concentration than the first and the second region,
wherein the first region and the second region form a Zener diode.

2. The lateral semiconductor device of claim 1, wherein a doping concentration of the first region at an interface to the intermediate region and a doping concentration of the second region at an interface to the intermediate region both exceed 1×10¹⁸ cm⁻³.

3. The lateral semiconductor device of claim 1, wherein a first lateral distance between the first region and the second region defined by the intermediate region is at most 800 nm.

4. A lateral semiconductor device, comprising:
a semiconductor substrate;
a first insulator layer formed on the semiconductor substrate; and
a semiconductor layer formed on the first insulator layer opposite to the semiconductor substrate,
wherein the semiconductor layer comprises:
a first region of a first conductivity type;
a second region of a second conductivity type opposite to the first conductivity type; and
an intermediate region interposed between the first region and the second region and defining a first lateral distance between the first region and the second region,
wherein the intermediate region comprises a lower doping concentration than the first region and the second region,
wherein a doping concentration of the first region at an interface to the intermediate region and a doping concentration of the second region at an interface to the intermediate region both exceed 1×10¹⁸ cm⁻³,
wherein the first lateral distance is at most 800 nm.

5. The lateral semiconductor device of claim 4, wherein the first lateral distance equals a lateral extension of the intermediate region between the first region and the second region.

6. The lateral semiconductor device of claim 4, wherein the intermediate region fully separates the first region and the second region.

7. The lateral semiconductor device of claim 4, wherein the intermediate region extends vertically over a full thickness of the semiconductor layer.

8. The lateral semiconductor device of claim 4, wherein each of the first region, the second region and the intermediate region adjoin the first insulator layer.

9. The lateral semiconductor device of claim 4, further comprising a second insulator layer formed on the semiconductor layer opposite to the first insulator layer.

10. The lateral semiconductor device of claim 9, wherein each of the first region, the second region and the intermediate region adjoin both the first insulator layer and the second insulator layer.

11. The lateral semiconductor device of claim 9, wherein at least between the first insulator layer and the second insulator layer, the first region and the second region interface only via the intermediate region.

12. The lateral semiconductor device of claim 4, wherein the doping concentration of the intermediate region is at least by a factor of two smaller than in the first region or the second region.

13. The lateral semiconductor device of claim 4, wherein the doping concentration of the intermediate region is smaller than 1×10¹⁸ cm⁻³.

14. The lateral semiconductor device of claim 4, wherein the intermediate region is monocrystalline.

15. The lateral semiconductor device of claim 4, wherein each of the first region, the second region and the intermediate region is at least partly monocrystalline.

16. The lateral semiconductor device of claim 4, wherein the semiconductor layer has a thickness of at most 400 nm.

17. The lateral semiconductor device of claim 4, further comprising:
a first field stop region adjoining the first semiconductor region; and
a second field stop region adjoining the second semiconductor region,
wherein the intermediate region further separates the first field stop region and the second field stop region.

18. A method for forming a lateral semiconductor device, the method comprising:
providing a semiconductor stack comprising a semiconductor substrate, a first insulator layer formed on the semiconductor substrate, and a semiconductor layer formed on the first insulator layer opposite to the semiconductor substrate; and
forming a Zener diode,
wherein forming the Zener diode comprises:
implanting first dopants to form a first region of a first conductivity type within the semiconductor layer; and
implanting second dopants to form a second region of a second conductivity type opposite to the first conductivity type within the semiconductor layer,
wherein the first dopants and the second dopants are implanted with a second lateral distance from each other to form an intermediate region interposed between the first region and the second region,
wherein the intermediate region comprises a lower doping concentration than the first region and the second region.

19. The method of claim 18, further comprising:
after implanting the first dopants and the second dopants, thermal annealing the semiconductor layer to form active pn junction.

20. The method of claim 18, further comprising:
after implanting the first dopants and the second dopants, recrystallizing at least portions of the first region and the second region.

21. A method for forming a lateral semiconductor device, the method comprising:
providing a semiconductor stack comprising a semiconductor substrate, a first insulator layer formed on the semiconductor substrate, and a semiconductor layer formed on the first insulator layer opposite to the semiconductor substrate;
implanting first dopants to form a first region of a first conductivity type within the semiconductor layer;
implanting second dopants to form a second region of a second conductivity type opposite to the first conductivity type within the semiconductor layer, wherein the first dopants and the second dopants are implanted with a second lateral distance of 50 nm to 800 nm; and
after implanting the first dopants and the second dopants, recrystallizing at least portions of the first region and the second region.
